(19) United States
(12) Patent Application Publication
(10) Pub. No.: US 2026/0317351 A1
(43) Pub. Date: Oct. 15, 2026

(54) SILICON-CONTAINING FILM PRECURSOR, COMPOSITION FOR FORMING SILICON-CONTAINING FILM, METHOD FOR MANUFACTURING SULFUR-CONTAINING SILOXANE, AND METHOD FOR MANUFACTURING SILICON-CONTAINING FILM

(71) Applicant: SUMITOMO SEIKA CHEMICALS CO., LTD., Hyogo (JP)

(72) Inventors: Genki TAIRA, Hyogo (JP); Yoshihide UENO, Hyogo (JP)

(73) Assignee: SUMITOMO SEIKA CHEMICALS CO., LTD., Hyogo (JP)

(21) Appl. No.: 19/114,625

(22) PCT Filed: Oct. 6, 2023
(86) PCT No.: PCT/JP2023/036524

§ 371 Date: Mar. 24, 2025

(30) Foreign Application Priority Data
Oct. 11, 2022 (JP) 2022-163442

(51) Int. Cl. C07F 7/21; C23C 16/40; C23C 16/455; H10P 14/60; H10P 14/692

(52) U.S. Cl. CPC C07F 7/21; C23C 16/401; C23C 16/45553; H10P 14/6686; H10P 14/69215

(57) ABSTRACT

Provided is a siloxane compound that can be used as a siloxane-containing film precursor with which it is possible, in the formation of a silicon-containing film, to form a film, for example, by atomic layer deposition (ALD) even in high-temperature conditions, by a sulfur-containing siloxane.

Provided is a siloxane compound that can be used as a siloxane-containing film precursor with which it is possible, in the formation of a silicon-containing film, to form a film by atomic layer deposition (ALD) even in high-temperature conditions, by a sulfur-containing siloxane represented by formula (1) (where: R¹ to R³ are, independently in each occurrence, a hydrogen atom, a C1-5 alkyl group, a C2-5 alkenyl group, a C2-5 alkynyl group, or a C1-5 alkoxy group; R¹ to R⁸ may each bond with each other to form a ring; X¹ to X³ are, independently in each occurrence, an oxygen atom or a sulfur atom; and n is an integer from 0 to 2).

### TECHNICAL FIELD

The technical field of the present disclosure is related to a sulfur-containing siloxane, a method for producing a silicon-containing film using the compound, and the like.

### BACKGROUND ART

In production of semiconductor devices, silicon-containing thin films are produced as thin films in various forms such as silicon films, silicon oxide films, silicon nitride films, silicon carbonitride films, and silicon oxynitride films by various vapor deposition processes, and are applied in various fields. Of these, silicon oxide films and silicon nitride films have an extremely excellent barrier properties and oxidation resistance and, therefore, function as insulating films, intermetal dielectric substances, seed layers, spacers, hard masks, trench isolations, diffusion preventing films, etching-stop layers, and protection-film layers in production of devices.

In recent years, with microfabrication of elements, increase in aspect ratios, and diversification of element materials, a technique for deposition by an atomic layer deposition (ALD) process, which may form a uniform film, has been required. Also, in recent years, there is a demand for a high-quality film containing few impurities and having an excellent electric property. As one of the solutions for forming the high-quality film, a method of deposition at high temperature of 500° C. or more has attracted attention. However, conventional deposition materials often decompose at high temperature, making deposition by the atomic layer deposition (ALD) process difficult. Occurrence of the decomposition makes self-control of deposition difficult and, accordingly, formation of a uniform film may become difficult, resulting in failure in achieving deposition in a high aspect ratio accompanying the microfabrication and the like. Therefore, a material that may be deposited by the ALD process without decomposing even under high-temperature conditions is in demand.

Patent Literature 1 proposes a method for forming, by the atomic layer deposition (ALD) process, a uniform silicon oxide film by using bisdiethylaminosilane (BDEAS), which is an aminosilane compound, as a silicon source by way of example of the conventional deposition materials.

Patent Literature 2 proposes a method for forming, by the atomic layer deposition (ALD) process, a uniform silicon oxide film at a high deposition rate by using 2-dimethylamino-2,4,6,8-tetramethylcyclotetrasiloxane, which is an aminosilane compound, as a silicon source.

Patent Literature 3 proposes a method for forming, by the atomic layer deposition (ALD) process, a uniform silicon oxide film at a high temperature by using dimethylaminotrimethylsilane (DMATMS), which is an aminosilane compound, as a silicon source.

### CITATION LIST

### Patent Literature

Patent Literature 1: Japanese Translation of PCT International Application Publication No. 2008-533731
Patent Literature 2: Japanese Patent Laid-Open No. 2018-154615
Patent Literature 3: Japanese Patent Laid-Open No. 2020-038978

### SUMMARY OF INVENTION

### Technical Problem

The bisdiethylaminosilane disclosed in Patent Literature 1 and the 2-dimethylamino-2,4,6,8-tetramethylcyclotetrasiloxane disclosed in Patent Literature 2 may each form a silicon oxide film by the atomic layer deposition (ALD) at 200 to 400° C. and at 100 to 300° C., respectively, but the temperature range is low and, therefore, where the deposition is attempted at a high temperature of 500° C. or more, the deposition material may be decomposed, resulting in failure in uniform deposition. In addition, the dimethylaminotrimethylsilane disclosed in Patent Literature 3 may form a silicon oxide film by the ALD process at 500 to 650° C., which is higher than the above film-forming temperatures of the bisdiethylaminosilane disclosed in Patent Literature 1 and the 2-dimethylamino-2,4,6,8-tetramethylcyclotetrasiloxane disclosed in Patent Literature 2, but it is still difficult to say that the high-temperature condition is sufficient.

The present disclosure has been devised in view of such situations, and a main object of the present disclosure is to provide a siloxane compound that may be used as a new silicon-containing film precursor that can be deposited by the atomic layer deposition (ALD) process even under high-temperature conditions, in order to form a silicon-containing film.

### Solution to Problem

Conventionally, it has been common to use an aminosilane compound in which an amino group is bonded to a silicon atom as a precursor for forming a silicon-containing film (silicon-containing film precursor). However, the present inventors conducted intensive studies and, as a result, found that using a thiosilane compound in which a sulfur atom is bonded to a silicon atom as a silicon-containing film precursor is useful in order to obtain a desired effect. In particular, they found that film forming by the atomic layer deposition (ALD) process under higher-temperature conditions may be achieved by using a specific compound in which a sulfur atom is bonded to a silicon atom having a siloxane structure (—Si—O—) as a silicon-containing film precursor, thereby completing the present disclosure.

Examples of the embodiments of the present disclosure are as follows.

### [Item 1]

A silicon-containing film precursor comprising a sulfur-containing siloxane represented by the formula (1):

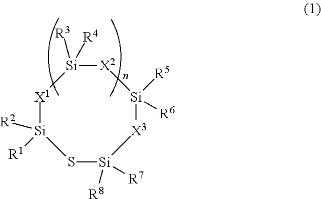

wherein R¹ to R⁸ is, independently in each occurrence, a hydrogen atom, an alkyl group having 1 to 5 carbon atoms, an alkenyl group having 2 to 5 carbon atoms, an alkynyl group having 2 to 5 carbon atoms, or an alkoxy group having 1 to 5 carbon atoms, and R¹ to R⁸ may each be bonded to each other to form a ring,
wherein X¹ to X³ is, independently in each occurrence, an oxygen atom or a sulfur atom, and
wherein n is an integer of 0 to 2.

### [Item 2]

The silicon-containing film precursor according to Item 1, wherein X¹ to X³ are oxygen atoms.

### [Item 3]

The silicon-containing film precursor according to Item 1 or 2, wherein the sulfur-containing siloxane is represented by the formula (2):

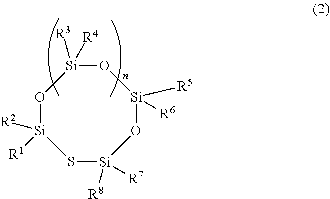

wherein R¹ to R⁸ is, independently in each occurrence, a hydrogen atom, an alkyl group having 1 to 5 carbon atoms, or an alkoxy group having 1 to 5 carbon atoms, and
wherein n is an integer of 0 to 2.

### [Item 4]

The silicon-containing film precursor according to any one of Items 1 to 3, wherein R¹ to R⁸ is, independently in each occurrence, an alkyl group having 1 to 5 carbon atoms.

### [Item 5]

The silicon-containing film precursor according to any one of Items 1 to 4, wherein the sulfur-containing siloxane is 2,2,4,4,6,6,8,8-octamethyl-1,3,5-trioxa-7-thia-2,4,6,8-tetrasilacyclooctane represented by the formula (3):

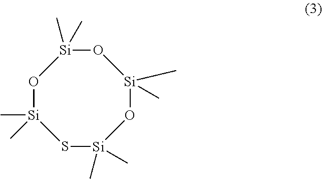

### [Item 6]

The silicon-containing film precursor according to any one of Items 1 to 5, wherein the silicon-containing film is formed by chemical vapor deposition.

### [Item 7]

The silicon-containing film precursor according to any one of Items 1 to 6, wherein the silicon-containing film is formed by an atomic layer deposition process.

### [Item 8]

A composition for forming a silicon-containing film comprising a sulfur-containing siloxane represented by the formula (1):

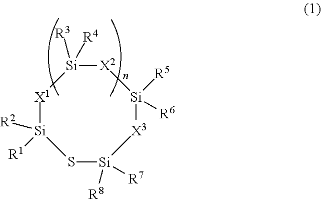

wherein R¹ to R⁸ is, independently in each occurrence, a hydrogen atom, an alkyl group having 1 to 5 carbon atoms, an alkenyl group having 2 to 5 carbon atoms, an alkynyl group having 2 to 5 carbon atoms, or an alkoxy group having 1 to 5 carbon atoms, and R¹ to R⁸ may each be bonded to each other to form a ring,
wherein X¹ to X³ is, independently in each occurrence, an oxygen atom or a sulfur atom, and
wherein n is an integer of 0 to 2.

### [Item 9]

A method for producing a sulfur-containing siloxane represented by the formula (1):

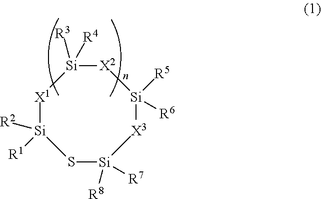

wherein R¹ to R⁸ is, independently in each occurrence, a hydrogen atom, an alkyl group having 1 to 5 carbon atoms, an alkenyl group having 2 to 5 carbon atoms, an alkynyl group having 2 to 5 carbon atoms, or an alkoxy group having 1 to 5 carbon atoms, and R¹ to R⁸ may each be bonded to each other to form a ring,
wherein X¹ to X³ is, independently in each occurrence, an oxygen atom or a sulfur atom, and
wherein n is an integer of 0 to 2,
the method comprising:
(a) a step of synthesizing the sulfur-containing siloxane from a raw material siloxane, and
(b) a distillation step of isolating the sulfur-containing siloxane by distillation.

### [Item 10]

The method for producing the sulfur-containing siloxane according to Item 9, wherein the raw material siloxane is reacted with a sulfurizing agent to synthesize the sulfur-containing siloxane in the step (a).

### [Item 11]

The method for producing the sulfur-containing siloxane according to Item 9 or 10, wherein the raw material siloxane is represented by a following formula (4):

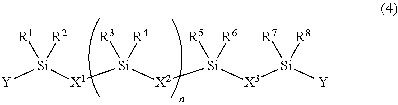

wherein R¹ to R⁸ is, independently in each occurrence, a hydrogen atom, an alkyl group having 1 to 5 carbon atoms, an alkenyl group having 2 to 5 carbon atoms, an alkynyl group having 2 to 5 carbon atoms, or an alkoxy group having 1 to 5 carbon atoms, and R¹ to R⁸ may each be bonded to each other to form a ring,
wherein X¹ to X³ is, independently in each occurrence, an oxygen atom or a sulfur atom,
wherein Y is a hydrogen atom or a halogen atom, and
wherein n is an integer of 0 to 2.

### [Item 12]

A method for producing a silicon-containing film using a sulfur-containing siloxane represented by the formula (1):

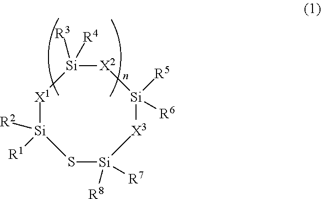

wherein R¹ to R⁸ is, independently in each occurrence, a hydrogen atom, an alkyl group having 1 to 5 carbon atoms, an alkenyl group having 2 to 5 carbon atoms, an alkynyl group having 2 to 5 carbon atoms, or an alkoxy group having 1 to 5 carbon atoms, and R¹ to R⁸ may each be bonded to each other to form a ring,
wherein X¹ to X³ is, independently in each occurrence, an oxygen atom or a sulfur atom, and
wherein n is an integer of 0 to 2.

### Advantageous Effect of Invention

According to the present disclosure, a uniform good-quality film may be formed by the ALD process under higher-temperature conditions by using a siloxane compound having a specific sulfur atom as a silicon-containing film precursor. For example, by the method of the present disclosure, the obtained silicon film may exhibit a preferable shrinkage and/or a preferable etching rate. Therefore, according to the method of the present disclosure, forming a film being uniform and excellent in the film property even under high-temperature conditions is possible, allowing for production of a high-performance semiconductor device.

### BRIEF DESCRIPTION OF DRAWINGS

FIG. 1 shows the ¹H-NMR chart of 2,2,4,4,6,6,8,8-octamethyl-1,3,5-trioxa-7-thia-2,4,6,8-tetrasilacyclooctane obtained by the production method in Example 1 of the present disclosure.

FIG. 2 shows the relation between the substrate temperature and the deposition rate in Example 2 and Comparative Examples 1 to 3 of the present disclosure.

### DESCRIPTION OF EMBODIMENTS

### <Sulfur-Containing Siloxane>

The sulfur-containing siloxane of the present disclosure has at least one sulfur atom and a cyclic structure.

The sulfur-containing siloxane of the present disclosure is represented by the following formula (1):

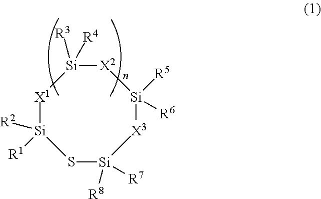

wherein R¹ to R⁸ is, independently in each occurrence, a hydrogen atom, an alkyl group having 1 to 5 carbon atoms, an alkenyl group having 2 to 5 carbon atoms, an alkynyl group having 2 to 5 carbon atoms, or an alkoxy group having 1 to 5 carbon atoms, and R¹ to R⁸ may each be bonded to each other to form a ring,
wherein X¹ to X³ is, independently in each occurrence, an oxygen atom or a sulfur atom, and
wherein n is an integer of 0 to 2.
   [R¹ to R⁸]

R¹ to R⁸ is, independently in each occurrence, a hydrogen atom, an alkyl group (for example, methyl, ethyl, propyl, isopropyl, n-butyl, sec-butyl, isobutyl, tert-butyl, pentyl) having 1 to 5 carbon atoms (for example, 1 to 3, 1 to 2, 1), an alkenyl group (for example, vinyl or 2-propenyl) having 2 to 5 carbon atoms (for example, 2 to 4, 2 to 3, and 2), an alkynyl group (for example, ethynyl or propynyl) having 2 to 5 carbon atoms (for example, 2 to 4, 2 to 3, and 2), or an alkoxy group (for example, methoxy, ethoxy, propoxy) having 1 to 5 carbon atoms (for example, 1 to 3, 1 to 2, and 1).

The average carbon number of R¹ to R⁸ may be 0.5 or more, 1 or more, 2 or more, or 3 or more, and is preferably 1 or more. The average carbon number of R¹ to R⁸ may be 5 or less, 4 or less, 3 or less, 2 or less, or 1, and is preferably 3 or less, which is for example, 2 or less.

R¹ to R⁸ may be each linear, branched, or cyclic, and R¹ to R⁸ are preferably linear or branched and more preferably linear.

R¹ to R⁸ may or may not be each bonded to each other to form a ring (where a ring is formed, one of R¹ to R⁸ may form a ring with, for example, another one of R¹ to R⁸ bonded to the same silicon atom or an adjacent silicon atom). Here, the bonding may refer to bonding in which bonds that respective R¹ to R⁸ have (for example, a bond resulting from elimination of a hydrogen atom of each of R¹ to R⁸) are bonded to each other.

At least one of R¹ to R⁸ (for example, 1 or more, 2 or more, 3 or more, 4 or more, or 5 or more) may be each a hydrocarbon group or an alkoxy group (for example, a hydrocarbon group, in particular, an alkyl group). All of R¹ to R⁸ may be each other than a hydrogen atom. The number of R¹ to R⁸ which is a hydrocarbon group or an alkoxy group (for example, a hydrocarbon group, in particular, an alkyl group) may be, based on the total number of R¹ to R⁸, 10% or more, 20% or more, 30% or more, 40% or more, 50% or more, 60% or more, 70% or more, 80% or more, or 90% or more, and is preferably 50% or more. The number of R¹ to R⁸ which is a hydrocarbon group or an alkoxy group (for example, a hydrocarbon group, in particular, an alkyl group) may be, based on the total number of R¹ to R⁸, 100% or less, 95% or less, 85% or less, 75% or less, or 65% or less. All of R¹ to R⁸ may be each a hydrocarbon group or an alkoxy group (for example, a hydrocarbon group, in particular, an alkyl group).

R¹ to R⁸ may be the same or different and, for example, may be the same. Suitable examples include a case where all of R¹ to R⁸ are an alkyl group, in particular, a methyl group.

[X¹ to X³]

X¹ to X³ is, independently in each occurrence, an oxygen atom or a sulfur atom.

At least one of X¹ to X³ (for example, 1 or more, 2 or more, 3 or more, or 4) may be each an oxygen atom. The number of X¹ to X³ which is an oxygen atom may be, based on the total number of X¹ to X³, 20% or more, 40% or more, 60% or more, or 80% or more, and is preferably 40% or more. The number of X¹ to X³ which is an oxygen atom may be, based on the total number of X¹ to X³, 100% or less, 70% or less, or 40% or less. All of X¹ to X³ may be each an oxygen atom.

[n]

n is an integer of 0 to 2, that is, 0, 1, or 2. For example, n is 0 or 1, 0 or 2, or 1 or 2, and in particular, 1.

### [Others]

The molecular weight of the sulfur-containing siloxane may be 200 or more, 250 or more, 300 or more, 350 or more, 400 or more, 450 or more, 500 or more, 550 or more, or 600 or more, and is preferably 300 or more. The molecular weight of the sulfur-containing siloxane may be 1000 or less, 900 or less, 800 or less, 700 or less, 600 or less, 500 or less, 400 or less, or 350 or less and is preferably 400 or less.

The carbon number of the sulfur-containing siloxane may be 0 or more, 1 or more, 4 or more, 6 or more, 8 or more, 10 or more, 12 or more, 15 or more, or 20 or more, and is preferably 6 or more. The carbon number of the sulfur-containing siloxane may be 50 or less, 40 or less, 30 or less, 25 or less, 20 or less, 15 or less, or 10 or less, and is preferably 20 or less.

If a large number of Si—O structures are present in one molecule, the element constituent is similar to the film composition in forming a silicon oxide film, which is preferred from the viewpoint of the film property. On the other hand, although the detailed reason is unclear, the presence of a Si—S structure facilitates deposition by ALD under high-temperature conditions. On the other hand, from the viewpoint of deposition and vapor-pressure control, the molecular size is also important. The present inventors conducted intensive studies and, as a result, found that a preferable effect may be achieved by a sulfur-containing siloxane having an appropriate number of Si—O structures and an appropriate molecular weight specified above.

### [Example of Sulfur-Containing Siloxane]

Examples of the sulfur-containing siloxane include a compound represented by the formula (2):

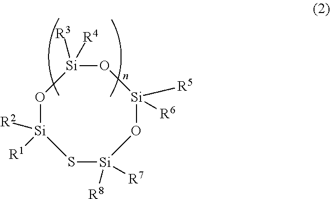

wherein R¹ to R⁸ is, independently in each occurrence, a hydrogen atom, an alkyl group having 1 to 5 carbon atoms, or an alkoxy group having 1 to 5 carbon atoms, and
wherein n is an integer of 0 to 2.

The detail of R¹ to R⁸ and n in the formula (2) is as described in the above description on the formula (1).

Specific examples of the sulfur-containing siloxane of the present disclosure include 2,2,4,4,6,6,8,8-octamethyl-1,3,5-trioxa-7-thia-2,4,6,8-tetrasilacyclooctane, 1,3-dioxa-5-thia-2,4,6-trisilacyclohexane, 2,2,4,4,6,6-hexamethyl-1,3-dioxa-5-thia-2,4,6-trisilacyclohexane, 2,2,4,4,6,6-hexaethyl-1,3-dioxa-5-thia-2,4,6-trisilacyclohexane, 2,2,4,4,6,6-hexavinyl-1,3-dioxa-5-thia-2,4,6-trisilacyclohexane, 2,2,4,4,6,6-hexapropyl-1,3-dioxa-5-thia-2,4,6-trisilacyclohexane, 2,2,4,4,6,6-hexaisopropyl-1,3-dioxa-5-thia-2,4,6-trisilacyclohexane, 2,2,4,4,6,6-hexabutyl-1,3-dioxa-5-thia-2,4,6-trisilacyclohexane, 1,3,5-trioxa-7-thia-2,4,6,8-tetrasilacyclooctane, 2,2,4,4,6,6,8,8-octaethyl-1,3,5-trioxa-7-thia-2,4,6,8-tetrasilacyclooctane, 2,2,4,4,6,6,8,8-octavinyl-1,3,5-trioxa-7-thia-2,4,6,8-tetrasilacyclooctane, 2,2,4,4,6,6,8,8-octapropyl-1,3,5-trioxa-7-thia-2,4,6,8-tetrasilacyclooctane, 2,2,4,4,6,6,8,8-octaisopropyl-1,3,5-trioxa-7-thia-2,4,6,8-tetrasilacyclooctane, 2,2,4,4,6,6,8,8-octabutyl-1,3,5-trioxa-7-thia-2,4,6,8-tetrasilacyclooctane, 1,3,5,7-tetraoxa-9-thia-2,4,6,8,10-pentasilacyclodecane, 2,2,4,4,6,6,8,8,10,10-decamethyl-1,3,5,7-tetraoxa-9-thia-2,4,6,8,10-pentasilacyclodecane, 2,2,4,4,6,6,8,8,10,10-decaethyl-1,3,5,7-tetraoxa-9-thia-2,4,6,8,10-pentasilacyclodecane, 2,2,4,4,6,6,8,8,10,10-decavinyl-1,3,5,7-tetraoxa-9-thia-2,4,6,8,10-pentasilacyclodecane, 2,2,4,4,6,6,8,8,10,10-decapropyl-1,3,5,7-tetraoxa-9-thia-2,4,6,8,10-pentasilacyclodecane, 2,2,4,4,6,6,8,8,10,10-decaisopropyl-1,3,5,7-tetraoxa-9-thia-2,4,6,8,10-pentasilacyclodecane, and 2,2,4,4,6,6,8,8,10,10-decabutyl-1,3,5,7-tetraoxa-9-thia-2,4,6,8,10-pentasilacyclodecane.

### <Method for Producing Sulfur-Containing Siloxane>

The method for producing the sulfur-containing siloxane of the present disclosure may include a production method including (a) a step of synthesizing the sulfur-containing siloxane from a raw material siloxane, and (b) a distillation step of isolating the sulfur-containing siloxane by distillation.

[Synthesizing Step (a)]

The synthesizing step (a) may include a step of reacting the raw material siloxane with a sulfurizing agent.

The raw material siloxane may be a compound represented by the following formula (4):

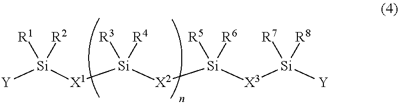

wherein R¹ to R⁸ is, independently in each occurrence, a hydrogen atom, an alkyl group having 1 to 5 carbon atoms, an alkenyl group having 2 to 5 carbon atoms, an alkynyl group having 2 to 5 carbon atoms, or an alkoxy group having 1 to 5 carbon atoms, and R¹ to R⁸ may each be bonded to each other to form a ring,
wherein X¹ to X³ is, independently in each occurrence, an oxygen atom or a sulfur atom,
wherein Y is a hydrogen atom or a halogen atom, and
wherein n is an integer of 0 to 2.

The detail of R¹ to R⁸ and n in the formula (4) is as described in the above description on the formula (1).

Y is a hydrogen atom or a halogen atom. Examples of Y include a hydrogen atom, a fluorine atom, a chlorine atom, a bromine atom, and an iodine atom.

The siloxane compound in which Y is a hydrogen atom may be used as it is in the synthesizing step (a), or the synthesizing step (a) may be performed after substituting Y with a halogen by using a halogenating agent. The halogenating agent may be a fluorinating agent, a chlorinating agent, a brominating agent, or an iodinating agent. Of these, chlorinating agents such as N-chlorosuccinimide and N-chlorophthalimide are preferably used.

The molecular weight of the raw material siloxane may be 150 or more, 200 or more, 250 or more, 300 or more, 350 or more, 400 or more, 450 or more, 500 or more, or 550 or more, and is preferably 250 or more. The molecular weight of the raw material siloxane may be 1000 or less, 900 or less, 800 or less, 700 or less, 600 or less, 500 or less, 400 or less, 350 or less, or 300 or less, and is preferably 350 or less.

The sulfurizing agent is a sulfur compound that may substitute Y in —SiY with sulfur, and, for example, sulfides such as lithium sulfide, sodium sulfide, and hydrogen sulfide may be used.

An example of the formula of reaction between the raw material siloxane (4) and the sulfurizing agent is shown in the following formula (5):

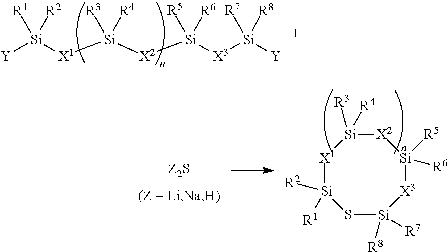

In the step (a), either of a method in which a raw material siloxane (for example, the raw material siloxane (4)) is dissolved in an organic solvent first and then the sulfurizing agent is added thereto, or a method in which the sulfurizing agent is dissolved in an organic solvent and then the raw material siloxane (for example, the raw material siloxane (4)) is added thereto may be applied to the reaction.

The amount of the sulfurizing agent to be used is, based on 1.0 mole of the raw material siloxane (for example, the raw material siloxane (4)), typically 0.2 to 3.0 moles, and preferably 0.4 to 2.0 moles.

The reaction may be performed at a temperature in the range of −20° C. to 100° C., and preferably −10° C. to 60° C. The reaction time is typically in the range of 0.5 to 30 hours.

Examples of the solvent that may be used for the present disclosure include: hydrocarbons such as hexane, cyclohexane, heptane, nonane, and decane; halogenated hydrocarbons such as dichloroethane, dichloromethane, and chloroform; aromatic hydrocarbons such as benzene, toluene, xylene, chlorobenzene, and trichlorobenzene; ethers such as diethyl ether, tetrahydrofuran (THF), and ethylene glycol dimethyl ether; and a mixture of these solvents. Of these, ethers such as diethyl ether and tetrahydrofuran (THF) are preferred, and in particular, tetrahydrofuran (THF) is preferably used. The amount of the solvent to be used is typically 0.1 to 50 times the mass of the raw material siloxane compound.

In order to avoid hydrolysis of siloxane and the sulfur-containing siloxane, the whole reaction system is desired to be under an anhydrous condition, and the reaction is performed in a range of the moisture content in all raw materials to be used of 0 to 5000 mass ppm, and preferably 0 to 500 mass ppm based on the mass of all of the raw materials. As a reaction device, it is desired to use a device that has been dried by heat-drying, reducing pressure, or performing substitution with an inert gas such as nitrogen and argon.

In the step (a), where a solid such as a byproduct salt is present in the reaction liquid, filtration may be performed after the reaction is completed as necessary. Where the filtration is performed, the filtration is desired to be performed in a dry inert gas such as nitrogen and argon in order to suppress decomposition of the sulfur-containing siloxane. The filtration temperature is not unconditionally specified, but a temperature of 10° C. to the boiling point of the solvent to be used may be applied. Preferably, the filtration is performed at a temperature in the range of 20° C. to 65° C.

[Distillation Step (b)]

In the step (b), the sulfur-containing siloxane is isolated by performing distillation, for example, reduced-pressure distillation. The sulfurizing agent and the organic solvent are easily removed, thereby allowing for purification of the sulfur-containing siloxane to a sufficiently high purity.

### <Method for Producing Silicon-Containing Film>

A silicon-containing film may be formed on a substrate by using the sulfur-containing siloxane of the present disclosure as an intermediate of the silicon-containing film. The method for forming the silicon-containing film of the present disclosure may be chemical vapor deposition, in particular, atomic layer deposition. More specifically, the method for forming the silicon-containing film of the present disclosure may be a chemical vapor deposition process (in particular, an atomic layer deposition process) comprising the steps of:
(c) bringing a substrate into contact with a sulfur-containing siloxane composition containing a sulfur-containing siloxane represented by the following formula (1) to allow the substrate to adsorb the sulfur-containing siloxane composition:

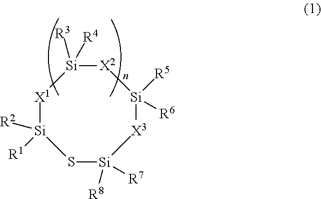

wherein R¹ to R⁸ is, independently in each occurrence, a hydrogen atom, an alkyl group having 1 to 5 carbon atoms, an alkenyl group having 2 to 5 carbon atoms, an alkynyl group having 2 to 5 carbon atoms, or an alkoxy group having 1 to 5 carbon atoms, and R¹ to R⁸ may each be bonded to each other to form a ring,
wherein X¹ to X³ is, independently in each occurrence, an oxygen atom or a sulfur atom, and
wherein n is an integer of 0 to 2;
(d) purging the sulfur-containing siloxane composition that has not been adsorbed and byproducts;
(e) injecting a reaction gas into the substrate that has adsorbed the sulfur-containing siloxane composition to decompose the sulfur-containing siloxane, thereby forming an atomic layer; and
(f) purging the unreacted reaction gas and byproducts.

The temperature of the substrate may be 100 to 800° C., and is preferably 100 to 750° C. From the viewpoint of the obtained film property, the temperature of the substrate may be 200° C. or more, 300° C. or more, 400° C. or more, 500° C. or more, 600° C. or more, or 700° C. or more, and is, for example, 250° C. or more. The temperature is preferably 300° C. or more, 400° C. or more, or 500° C. or more. The deposition temperature may be the temperature of at least one of the steps (c) to (f) and is, for example, the temperature of the substrate when brought into contact with the sulfur-containing siloxane composition in the step (c). The silicon-containing film obtained from the sulfur-containing siloxane of the present disclosure is stable even at high temperature and, therefore, the sulfur-containing siloxane of the present disclosure may be suitably used in the method for producing the silicon-containing film that employs a high substrate temperature as well.

The pressure during the gas injection in the steps (c) and (e) is 0.05 to 100 Torr and preferably 0.05 to 50 Torr. The sulfur-containing siloxane composition may contain, as a carrier gas, an inert gas such as nitrogen and argon.

In the step (e), where a silicon oxide film having a Si—O bond is formed, one or more gases selected from oxygen, ozone, and nitrogen monoxide may be used as reaction gases. Where a silicon nitride film having a Si—N bond is formed, one or more gases selected from nitrogen, ammonia, dinitrogen monoxide, nitrogen monoxide, and nitrogen dioxide may be used as reaction gases.

The formation of the silicon-containing film is desired to be performed after performing substitution with an inert gas such as nitrogen and argon. That is, the step (c) is preferably performed after performing substitution with an inert gas inside the reaction system.

The sulfur-containing siloxane of the present disclosure is suitably used for production of a silicon-containing film (such as a silicon oxide film and a silicon nitride film) by a chemical vapor deposition process (in particular, an atomic layer deposition process). In the method for producing the silicon-containing film of the present disclosure, the lower limit of the ALD window may be 300° C., and is preferably 350° C. In addition, in the method for producing the silicon-containing film of the present disclosure, the upper limit of the ALD window may be 800° C., and is preferably 750° C. Here, the ALD window generally refers to a temperature range between the temperature at which the silicon-containing film precursor compound is vaporized and the thermal-decomposition temperature of the silicon-containing film precursor compound, and the ALD window herein may be defined as a temperature range from the point at which the deposition rate is maximum to the point at which the deposition rate is minimum when the horizontal axis represents the deposition temperature and the vertical axis represents the deposition rate.

The embodiments are described above, but it will be understood that various modifications in forms and details are possible without departing from the gist and the scope of the claims.

### EXAMPLES

The present disclosure will hereinafter be described in detail with reference to Examples, but the present disclosure is not limited to these Examples.

### Example 1: Synthesis of 2,2,4,4,6,6,8,8-octamethyl-1,3,5-trioxa-7-thia-2,4,6,8-tetrasilacyclooctane

After substitution with nitrogen, 1.98 g (0.043 moles) of lithium sulfide and 317 g of tetrahydrofuran were added into a 500 mL flask equipped with a thermometer, a cooling pipe, and a motor-type stirrer. While stirring was performed at room temperature, 10.9 g (0.031 moles) of 1,7-dichloro-octamethyltetrasiloxane was slowly dropped. After the dropping, stirring was performed for 6 hours while maintaining the temperature of 20 to 26° C. Thereafter, tetrahydrofuran was removed by performing reduced-pressure distillation at an internal temperature of 50 to 60° C. Then, in a nitrogen-substituted glove box, solids, mainly byproduct lithium chloride, were removed by reduced-pressure filtration, and a solution containing 2,2,4,4,6,6,8,8-octamethyl-1,3,5-trioxa-7-thia-2,4,6,8-tetrasilacyclooctane was obtained. Thereafter, reduced-pressure distillation was performed at an internal temperature of 68° C. at 1.9 Torr to obtain 2,2,4,4,6,6,8,8-octamethyl-1,3,5-trioxa-7-thia-2,4,6,8-tetrasilacyclooctane of high purity.

By GC analysis after the distillation, it was confirmed that 5.7 g (yield: 58%) of 2,2,4,4,6,6,8,8-octamethyl-1,3,5-trioxa-7-thia-2,4,6,8-tetrasilacyclooctane with a purity of 98.3% area was obtained. The obtained 2,2,4,4,6,6,8,8-octamethyl-1,3,5-trioxa-7-thia-2,4,6,8-tetrasilacyclooctane was identified by ¹H-NMR and GC-MS. The ¹H-NMR assignments are as follows.

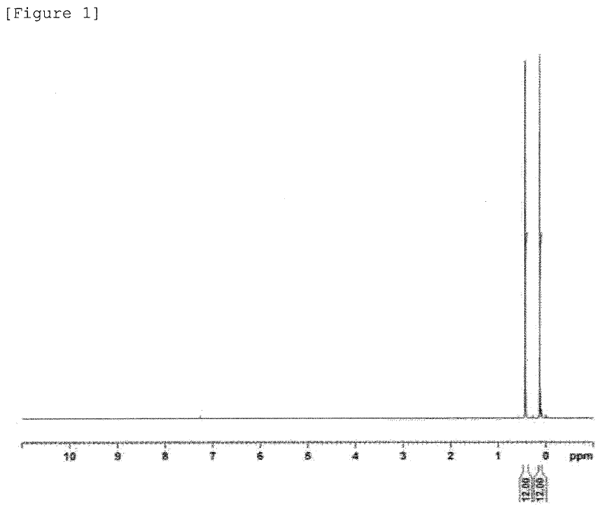

The ¹H-NMR chart is as shown in FIG. 1. ¹H-NMR (400 MHz, CDCl3): δ0.12 (s, 12H, [CH₃—Si]), δ0.43 (s, 12H, [CH₃—SiS])

From the above results of ¹H-NMR and GC-MS, the obtained sulfur-containing siloxane was identified to be 2,2,4,4,6,6,8,8-octamethyl-1,3,5-trioxa-7-thia-2,4,6,8-tetrasilacyclooctane as represented by the following formula.

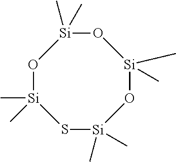

### Example 2: Formation of Silicon-Containing Film Using 2,2,4,4,6,6,8,8-octamethyl-1,3,5-trioxa-7-thia-2,4,6,8-tetrasilacyclooctane

A silicon substrate was placed in a vacuum device and heated to a predetermined temperature of 500 to 750° C. A siloxane composition containing the 2,2,4,4,6,6,8,8-octamethyl-1,3,5-trioxa-7-thia-2,4,6,8-tetrasilacyclooctane obtained in Example 1 and a carrier gas was injected at a pressure of 0.05 to 100 Torr to allow the heated silicon substrate to adsorb the composition. Next, argon gas was introduced to purge the sulfur-containing siloxane composition that had not been adsorbed in the device and byproducts. Thereafter, ozone as a reaction gas was injected at a pressure of 0.05 to 100 Torr to form an atomic layer of silicon oxide derived from the 2,2,4,4,6,6,8,8-octamethyl-1,3,5-trioxa-7-thia-2,4,6,8-tetrasilacyclooctane that had deposited on the substrate. Next, argon gas was introduced to purge the unreacted ozone and byproducts. The above cycle was repeated to obtain a silicon oxide film.

### Comparative Example 1: Formation of Silicon-Containing Film Using Bisdiethylaminosilane

A silicon substrate was placed in a vacuum device and heated to a predetermined temperature of 100 to 750° C. An aminosilane composition containing bisdiethylaminosilane and a carrier gas was injected at a pressure of 0.05 to 100 Torr to allow the heated silicon substrate to adsorb the composition. Next, argon gas was introduced to purge the aminosilane composition that had not been adsorbed in the device and byproducts. Thereafter, ozone as a reaction gas was injected at a pressure of 0.05 to 100 Torr to form an atomic layer of silicon oxide derived from the bisdiethylaminosilane that had deposited on the substrate. Next, argon gas was introduced to purge the unreacted ozone gas and byproducts. The above cycle was repeated to obtain a silicon oxide film.

### Comparative Example 2: Formation of Silicon-Containing Film Using 2-dimethylamino-2,4,6,8-tetramethylcyclotetrasiloxane

A silicon substrate was placed in a vacuum device and heated to a predetermined temperature of 100 to 750° C. A siloxane composition containing 2-dimethylamino-2,4,6,8-tetramethylcyclotetrasiloxane and a carrier gas was injected at a pressure of 0.05 to 100 Torr to allow the heated silicon substrate to adsorb the composition. Next, argon gas was introduced to purge the aminosiloxane composition that had not been adsorbed in the device and byproducts. Thereafter, ozone as a reaction gas was injected at a pressure of 0.05 to 100 Torr to form an atomic layer of silicon oxide derived from the 2-dimethylamino-2,4,6,8-tetramethylcyclotetrasiloxane that had deposited on the substrate. Next, argon gas was introduced to purge the unreacted ozone gas and byproducts. The above cycle was repeated to obtain a silicon oxide film.

### Comparative Example 3: Formation of Silicon-Containing Film Using 2,4,6,8-tetramethylcyclotetrasiloxane

A silicon substrate was placed in a vacuum device and heated to a predetermined temperature of 200 to 750° C. A siloxane composition containing 2,4,6,8-tetramethylcyclotetrasiloxane and a carrier gas was injected at a pressure of 0.05 to 100 Torr to allow the heated silicon substrate to adsorb the composition. Next, argon gas was introduced to purge the aminosiloxane composition that had not been adsorbed in the device and byproducts. Thereafter, ozone as a reaction gas was injected at a pressure of 0.05 to 100 Torr to form an atomic layer of silicon oxide derived from 2,4,6,8-tetramethylcyclotetrasiloxane that had deposited on the substrate. Next, argon gas was introduced to purge the unreacted ozone gas and byproducts. The above cycle was repeated to obtain a silicon oxide film.

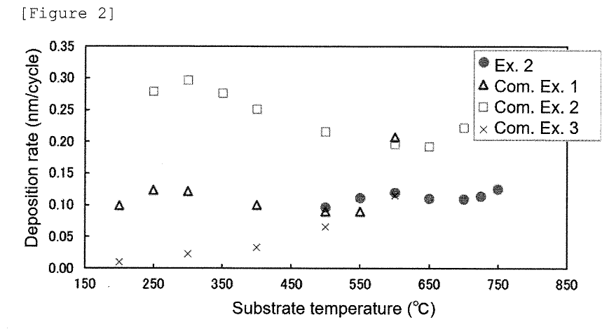

The specific vapor deposition method is shown in Table 1 below. The relation between the substrate temperature and the deposition rate is shown in FIG. 2. In measurement of each plot in FIG. 2, the siloxane supply time at which the deposition rate was maximum was selected. The deposition rates when the cycle was repeated 50 times at a substrate temperature of 725° C., which was the maximum temperature of the ALD window, and at a substrate temperature of 750° C., which was outside the ALD window, in Example 2 are shown in Table 2. Here, the ALD window shows a temperature range from the point at which the deposition rate is maximum to the point at which the deposition rate is minimum in FIG. 2. The temperature range of the ALD window for each of Example 1 and Comparative Examples 1 and 2 is shown in Table 3. The layer thickness was measured with an ellipsometer. The shrinkage of the film is shown in Table 4 which was deposited at a temperature near the upper limit of the ALD window (700° C. for Example and 550° C. for Comparative Example 1) and then annealed at 800° C. for 30 minutes. The etching rate of the film is shown in Table 5 which was deposited at a temperature near the upper limit of the ALD window (700° C. for Example and 500° C. for Comparative Example 1) and then immersed in 0.5% hydrofluoric acid for 60 seconds. The etching rate was calculated by measuring the film thicknesses before and after the immersion in the 0.5% hydrofluoric acid with an ellipsometer, calculating the amount of decrease in the film thickness, and then dividing the amount by the immersion time.

TABLE 1

| | | |
|---|---|---|
| Raw material | 3~12 seconds | Supply with Ar |
| supply | | |
| Ar purge 1 | 45 seconds | 50~170 sccm |
| Ozone supply | 6 seconds | 100 sccm |
| Ar purge 2 | 45 seconds | 50~170 sccm |

TABLE 2

| Siloxane supply | |
|---|---|
| time | Deposition rate |
| (seconds) | (nm/cycle) |
| (Example 2) | (725 °C) |
| 3 | 0.113 |
| 6 | 0.116 |
| 9 | — |
| 12 | 0.114 |

TABLE 3

| | Example | | | |
|---|---|---|---|---|
| | 2,2,4,4,6,6,8,8- | | | |
| | octamethyl- | | Comparative | |
| | 1,3,5- | | Example 2 | |
| | trioxa-7- | | 2- | Comparative |
| | thia- | Comparative | dimethylamino- | Example 3 |
| | 2,4,6,8- | Example 1 | 2,4,6,8- | 2,4,6,8- |
| | tetrasila- | Bisdiethyl- | tetramethylcyclo- | tetramethylcyclo- |
| Compound | cyclooctane | aminosilane | tetrasiloxane | tetrasiloxane |
| ALD | 600~725 °C | 250~550 °C | 300~650 °C | Impossible to |
| window | | | | perform ALD |
| | | | | film forming |

TABLE 4

| | Example | |
|---|---|---|
| | 2,2,4,4,6,6,8,8- | |
| | octamethyl-1,3,5- | |
| | trioxa-7-thia- | |
| | 2,4,6,8- | Comparative Example 1 |
| Compound | tetrasilacyclooctane | Bisdiethylaminosilane |
| Film | 30.95 nm | 32.76 nm |
| thickness | | |
| before | | |
| annealing | | |
| Film | 30.60 nm | 32.24 nm |
| thickness | | |
| after | | |
| annealing | | |
| Shrinkage | 1.1% | 1.6% |

TABLE 5

| | Example | |
|---|---|---|
| | 2,2,4,4,6,6,8,8- | |
| | octamethyl-1,3,5- | |
| | trioxa-7-thia- | |
| | 2,4,6,8- | Comparative Example 1 |
| Compound | tetrasilacyclooctane | Bisdiethylaminosilane |
| Etching | 0.82 | 1.66 |
| rate | | |

As shown in Table 2, in order to form an atomic layer of silicon oxide derived from a 2,2,4,4,6,6,8,8-octamethyl-1,3,5-trioxa-7-thia-2,4,6,8-tetrasilacyclooctane compound in Example 2, the supply time of a 2,2,4,4,6,6,8,8-octamethyl-1,3,5-trioxa-7-thia-2,4,6,8-tetrasilacyclooctane composition was considered. It was confirmed that the deposition rate reached its maximum when the supply time was 6 seconds or more at a substrate temperature of 725° C., whereby ALD deposition was established.

As shown in Table 3 and FIG. 2, it was confirmed that the temperature range (ALD window) in which 2,2,4,4,6,6,8,8-octamethyl-1,3,5-trioxa-7-thia-2,4,6,8-tetrasilacyclooctane could be deposited was on the higher-temperature side than the ALD windows of bisdiethylaminosilane and 2-dimethylamino-2,4,6,8-tetramethylcyclotetrasiloxane.

As shown in Tables 4 and 5, it was confirmed that 2,2,4,4,6,6,8,8-octamethyl-1,3,5-trioxa-7-thia-2,4,6,8-tetrasilacyclooctane may form a better-quality film having a lower shrinkage and a lower etching rate than bisdiethylaminosilane in ALD deposition.

### INDUSTRIAL APPLICABILITY

By using the method described in the present disclosure, an extremely thin silicon oxide film and the like having no atomic defects may be formed even on a semiconductor substrate, a nanowire, or the like having a high-aspect-ratio structure formed therein. In particular, the sulfur-containing siloxane of the present disclosure is useful for the atomic deposition process characterized by higher temperature deposition.

1. A silicon-containing film precursor comprising a sulfur-containing siloxane represented by the formula (1): 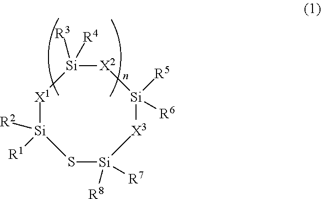
wherein R¹ to R⁸ is, independently in each occurrence, a hydrogen atom, an alkyl group having 1 to 5 carbon atoms, an alkenyl group having 2 to 5 carbon atoms, an alkynyl group having 2 to 5 carbon atoms, or an alkoxy group having 1 to 5 carbon atoms, and R¹ to R⁸ may each be bonded to each other to form a ring,
wherein X¹ to X³ is, independently in each occurrence, an oxygen atom or a sulfur atom, and
wherein n is an integer of 0 to 2.

2. The silicon-containing film precursor according to claim 1, wherein X¹ to X³ are oxygen atoms.

3. The silicon-containing film precursor according to claim 1, wherein the sulfur-containing siloxane is represented by the formula (2): 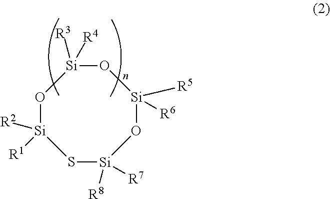
wherein R¹ to R⁸ is, independently in each occurrence, a hydrogen atom, an alkyl group having 1 to 5 carbon atoms, or an alkoxy group having 1 to 5 carbon atoms, and
wherein n is an integer of 0 to 2.

4. The silicon-containing film precursor according to claim 1, wherein R¹ to R⁸ is, independently in each occurrence, an alkyl group having 1 to 5 carbon atoms.

5. The silicon-containing film precursor according to claim 1, wherein the sulfur-containing siloxane is 2,2,4,4,6,6,8,8-octamethyl-1,3,5-trioxa-7-thia-2,4,6,8-tetrasilacyclooctane represented by the formula (3):

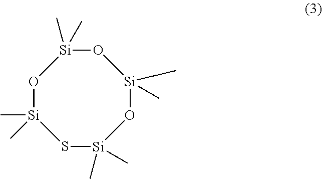

6. The silicon-containing film precursor according to claim 1, wherein the silicon-containing film is formed by chemical vapor deposition.

7. The silicon-containing film precursor according to claim 1, wherein the silicon-containing film is formed by an atomic layer deposition process.

8. A composition for forming the silicon-containing film of claim 1.

9. A method for producing a sulfur-containing siloxane represented by the formula (1): 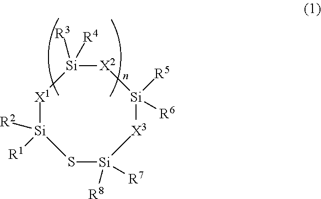
wherein R¹ to R⁸ is, independently in each occurrence, a hydrogen atom, an alkyl group having 1 to 5 carbon atoms, an alkenyl group having 2 to 5 carbon atoms, an alkynyl group having 2 to 5 carbon atoms, or an alkoxy group having 1 to 5 carbon atoms, and R¹ to R⁸ may each be bonded to each other to form a ring,
wherein X¹ to X³ is, independently in each occurrence, an oxygen atom or a sulfur atom, and
wherein n is an integer of 0 to 2,
the method comprising:
(a) a step of synthesizing the sulfur-containing siloxane from a raw material siloxane, and
(b) a distillation step of isolating the sulfur-containing siloxane by distillation.

10. The method for producing the sulfur-containing siloxane according to claim 9, wherein the raw material siloxane is reacted with a sulfurizing agent to synthesize the sulfur-containing siloxane in the step (a).

11. The method for producing the sulfur-containing siloxane according to claim 9, wherein the raw material siloxane is represented by a following formula (4): 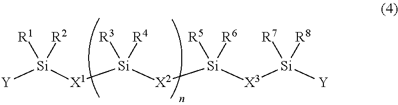
wherein R¹ to R⁸ is, independently in each occurrence, a hydrogen atom, an alkyl group having 1 to 5 carbon atoms, an alkenyl group having 2 to 5 carbon atoms, an alkynyl group having 2 to 5 carbon atoms, or an alkoxy group having 1 to 5 carbon atoms, and R¹ to R⁸ may each be bonded to each other to form a ring,
wherein X¹ to X³ is, independently in each occurrence, an oxygen atom or a sulfur atom,
wherein Y is a hydrogen atom or a halogen atom, and
wherein n is an integer of 0 to 2.

12. A method for producing a silicon-containing film using a sulfur-containing siloxane represented by the formula (1): 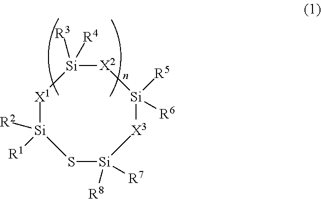
wherein R¹ to R⁸ is, independently in each occurrence, a hydrogen atom, an alkyl group having 1 to 5 carbon atoms, an alkenyl group having 2 to 5 carbon atoms, an alkynyl group having 2 to 5 carbon atoms, or an alkoxy group having 1 to 5 carbon atoms, and R¹ to R⁸ may each be bonded to each other to form a ring,
wherein X¹ to X³ is, independently in each occurrence, an oxygen atom or a sulfur atom, and
wherein n is an integer of 0 to 2.
